(19) United States
(12) Patent Application Publication
(10) Pub. No.: US 2008/0066679 A1
(43) Pub. Date: Mar. 20, 2008

(54) PROCESSING SYSTEM AND PLASMA GENERATION DEVICE

(75) Inventors: Chi-Hung Liu, Taichung County (TW); Wen-Tzong Hsieh, Taichung County (TW); Chen-Der Tsai, Hsinchu County (TW); Chun-Hsien Su, Hsinchu City (TW); Chih Wei Chen, Taipei County (TW); Chun-Hung Lin, Taipei City (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/564,826

(22) Filed: Nov. 29, 2006

(30) Foreign Application Priority Data
Sep. 14, 2006 (TW) TW95134000

(51) Int. Cl. C23F 1/00; C23C 16/00

(52) U.S. Cl. 118/723 E; 156/345.43

(57) ABSTRACT

A processing system is used for processing an object by a first fluid. The processing system includes a base and a plasma generation device. The base supports the object and the plasma generation device ionizes the first fluid. The plasma generation device includes at least one guiding element comprising a path guiding the first fluid to sequentially flow through a first position and a second position and at least one electrode element including a first electrode corresponding to the first position and a second electrode corresponding to the second position. The first and second electrodes energize the first fluid located between the first and second electrodes to form a second fluid, to thereby utilize the second fluid to perform surfacing, activating, cleaning, photoresist ashing or etching process on the object supported by the base.

### BACKGROUND OF THE INVENTION

1. Field of the Invention

The invention relates to a plasma generation device, and in more particularly to a processing system and a plasma generation device thereof providing wear-free electrodes.

2. Description of the Related Art

Recently, plasma containing high-energy particles, e.g. electron and ions, and active species are popular techniques for performing coating, etching, or surfacing processes on a work piece or products in the field such as photoelectronics, semiconductors, computers, communication, consumer electronics, automobile, civilian and biomedical materials. Additionally, studies and researches related to plasma techniques are rapidly developing.

For example, in the fields of photoelectronics and semiconductors, plasma must be performed in a vacuum environment requiring high cost vacuum equipment. Thus, high-cost the vacuum plasma technique limits the development of the conventional industries.

Some researchers have developed atmospheric plasma (or normal-pressure plasma) which is excited under atmospheric pressure without requiring a vacuum environment and has a much lower cost than the vacuum plasma technique, thus, a linearly atmospheric pressure plasma system can be constructed. In addition, the atmospheric pressure plasma system can provide an effective plasma region for processing a large area of the work piece and performing a series of roll-to-roll processes (which is limited by the chamber in a vacuum plasma system), thus the running cost of products can be reduced.

### BRIEF SUMMARY OF THE INVENTION

The invention provides a modulated processing system and a linear plasma generation device thereof for forming plasma by lossless electrodes, i.e., no contact between electrodes and plasma, thus, the equipment cost decreases and the yield can be increased.

The plasma generation device of the invention is used for ionizing a first fluid. The plasma generation device comprises at least one guiding element and at least one electrode element. The guiding element comprises a path guiding the first fluid to sequentially flow through a first position and a second position. The electrode element comprises a first electrode corresponding to the first position and a second electrode corresponding to the second position. The first and second electrodes energize the first fluid located between the first and second electrodes to form a second fluid. The energy state of the first fluid is different from that of the second fluid.

A processing system of the invention processes an object utilizing a first fluid. The processing system comprises a base and a plasma generation device. The base supports the object and the plasma generation device ionizes the first fluid. The plasma generation device comprises at least one guiding element comprising a path guiding the first fluid to sequentially flow through a first position and a second position and at least one electrode element comprising a first electrode corresponding to the first position and a second electrode corresponding to the second position. The first and second electrodes energize the first fluid located between the first and second electrodes to form a second fluid, to thereby utilize the second fluid to perform surfacing, activating, cleaning, photoresist ashing or etching processes on the object supported by the base.

A potential difference exists between the first and second electrodes. The guiding element comprises a hollow portion, and the path is located in the hollow portion of the guiding element.

The first and second electrodes can have the same size. The size of the first electrode can be greater than that of the second electrode.

The guiding element is enclosed by the first electrode. The guiding element is enclosed by the second electrode. The guiding element is partially enclosed by the first electrode. The first electrode comprises a similar C-shaped structure. The guiding element is partially enclosed by the second electrode. The second electrode comprises a similar C-shaped structure. The first electrode comprises a first slotted portion and the second electrode comprises a second slotted portion. The first and second slotted portions are arranged alternatively with respect to the path.

The plasma generation device further comprises a supply device electronically connected to the first electrode. The supply device is a radio frequency generator having a frequency equal to 13.56 MHz or a multiple of 13.56 MHz. The supply device is a power supply. The power supply is an AC generator having the frequency of the AC generator ranged from 1 MHz to 100 MHz.

The plasma generation device comprises a third position through which the second fluid passes and where the energy state curve of the second fluid is uniform. The guiding element comprises dielectric material. The first electrode is a coiled structure disposed outside of the guiding element.

The guiding element further comprises a sidewall portion and a port structure formed on the sidewall portion, wherein the second fluid passes through the port structure. The port structure is a hole.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic view of a plasma generation device (M1) of a first embodiment of the invention;

FIG. 2 is a schematic view of a plasma generation device (M2) of a second embodiment of the invention;

FIG. 3 is a schematic view of a plasma generation device (M3) of a third embodiment of the invention;

FIG. 4 is a schematic view of a plasma generation device (M4) of a fourth embodiment of the invention;

FIG. 5A is a schematic view of a processing system (T1a) of a first exemplary application of the invention, wherein the processing system (T1a) comprises a single plasma generation device (M1);

FIG. 5B is a varied example (T1b) of the processing system (T1a) of FIG. 5A;

FIG. 6 is a schematic view of a processing system (T1′) of a second exemplary application of the invention;

FIG. 7 is a schematic view of a processing system (T2) of a third exemplary application of the invention, wherein the processing system (T2) comprises a first electrode (1-5), a second electrode (2-5), and a plurality of guiding elements (P1) enclosed by the first and second electrodes (1-5) and (2-5);

FIG. 8A is a sectional view of the processing system (T2) along line (Z1-Z1) of FIG. 7, wherein the guiding elements (PI) are serially arranged;

FIG. 8B shows another configuration (arranged alternatively) of the guiding elements (P1) of the processing system (T2) in comparison with FIG. 8A;

FIG. 9A is a sectional view of the first electrode (1-5) along line (Z2-Z2) of FIG. 7, wherein the guiding elements (P1) located in the first electrode (1-5) are serially arranged; and

FIG. 9B shows another configuration (arranged alternatively) of the guiding elements (P1) located in the first electrode (1-5) in comparison with FIG. 9A.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

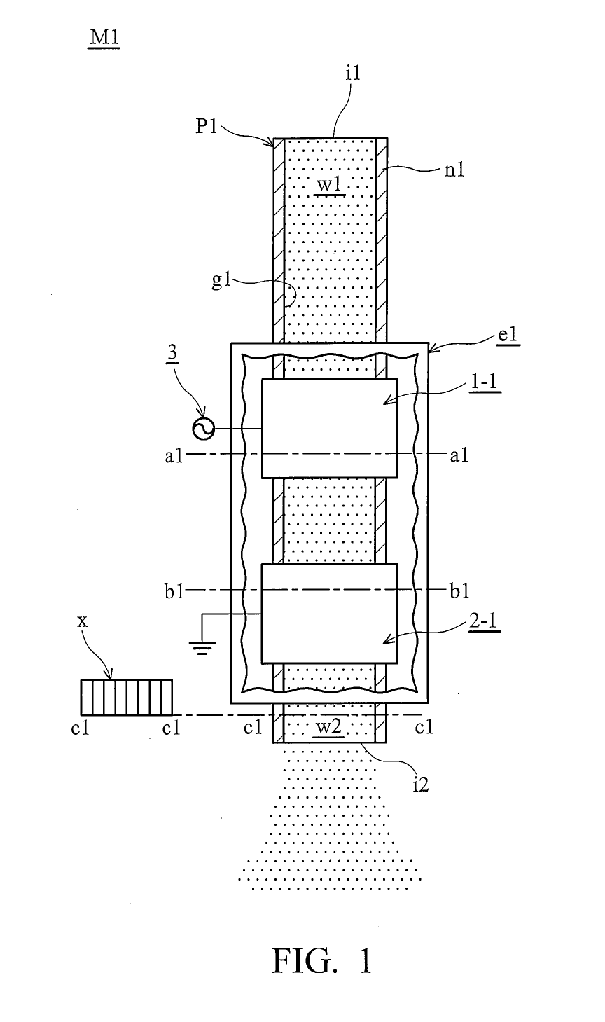

In FIG. 1, a plasma generation device M1 for ionizing a first fluid w1 such as air, gases of Ar, He, N₂, O₂ and mixture, comprises a guiding element P1, an electrode element e1 and a supply device 3.

The guiding element P1 comprises a hollow portion n1, a path g1 located in the hollow portion n1, a first position a1-a1, a second position b1-b1 and a third position c1-c1. The first, second and third positions a1-a1, b1-b1 and c1-c1 located at three different positions of the hollow portion i1, representing three sections of the path g1, respectively. An input end i1 and an output end i2 are respectively located at two ends of the hollow portion n1. When the first fluid w1 flows into the path g1 via the input end i1, the first fluid w1 sequentially passes through the first and second positions a1-a1 and b1-b1. In this embodiment, the guiding element P1 comprises dielectric material such as silex, ceramic materials, or other non-conductive materials with the same properties as silex or ceramic materials.

The electrode element e1 comprises a first electrode 1-1 and a second electrode 2-1. The first and second electrodes 1-1 and 2-1 respectively correspond to the first and second positions a1-a1 and b1-b1 to enclose the guiding elements P1. The supply device 3 provides signals or power to the first electrode 1-1. The second electrode 2-1 is grounded, having a potential difference with respect to the first electrode 1-1.

In this embodiment, the first and second electrodes 1-1 and 2-1 have the same size, and the supply device 3 is a radio frequency generator having the frequency of 13.56 MHz or a multiple of 13.56 MHz. The first electrode 1-1 receives signals from the radio frequency generator to energize the first fluid w1 located between the first and second electrodes 1-1 and 2-1. In addition, the power supply can be an AC generator having the frequency of the AC ranged from 1 MHz to 100 MHz. The AC generator electrically connected to the first electrode 1-1 to energize the first fluid w1 located between the first and second electrodes 1-1 and 2-1.

With respect to the first and second electrodes 1-1 and 2-1 corresponding to the first and second positions a1-a1 and b1-b1, respectively, the first and second electrodes 1-1 and 2-1 energize the first fluid w1 therebetween to form a second fluid w2 having an energy state different from that of the first fluid w1. The second fluid w2 passes through the third position c1-c1 and outputs from the output end i2 of the hollow portion n1. Note that the energy distribution curve x of the second fluid w2 located at the third position c1-c1 is substantially uniform.

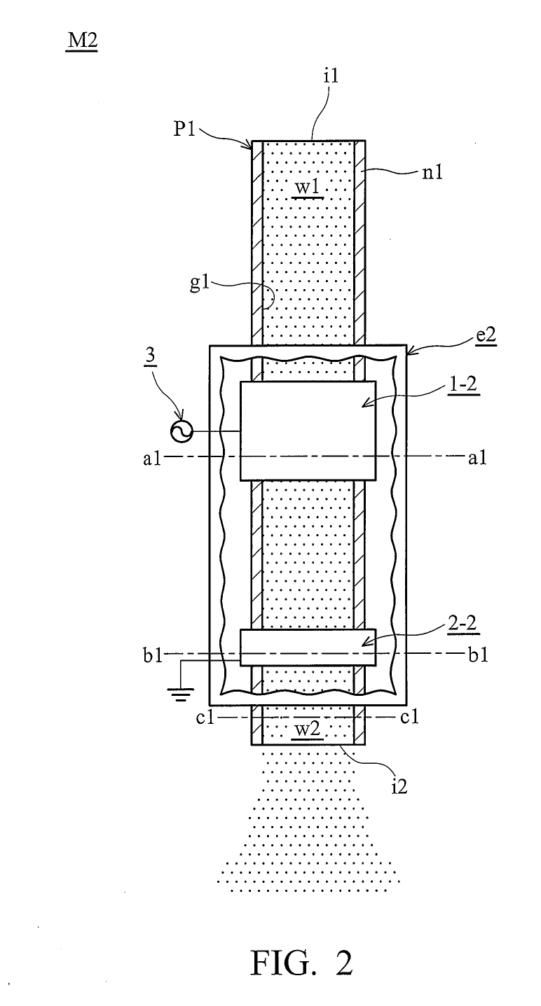

In FIG. 2, a plasma generation device M2 of a second embodiment of the invention comprises the guiding element P1, the supply device 3, and an electrode element e2 comprising a first electrode 1-2 and a second electrode 2-2. The plasma generation device M2 differs from the plasma generation device M1 of the first embodiment in that the size of the first electrode 1-2 is greater than that of the second electrode 2-2.

With respect to the first and second electrodes 1-2 and 2-2 corresponding to the first and second positions a1-a1 and b1-b1, respectively, the first and second electrodes 1-2 and 2-2 energize the first fluid w1 therebetween to form a second fluid w2 having an energy state different from that of the first fluid w1, and the second fluid, w2 passes through the third position c1-c1 and outputs from the output end i2 of the hollow portion n1.

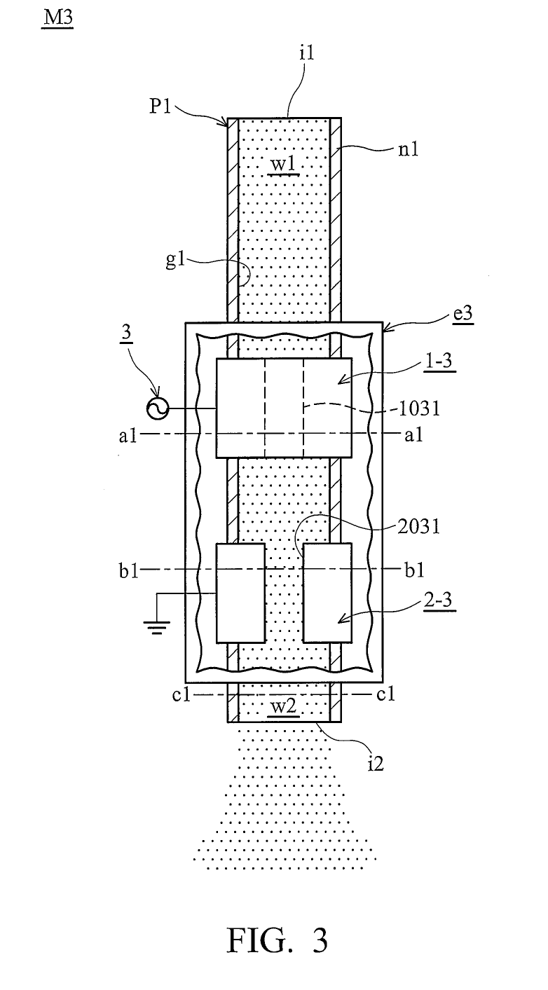

in FIG. 3, a plasma generation device M3 of a third embodiment of the invention comprises the guiding element P1, the supply device 3, and an electrode element e3 comprising a first electrode 1-3 formed with a first slotted portion 1031 and a second electrode 2-3 formed with a second slotted portion 2031. The plasma generation device M3 differs from the plasma generation device M1 of the first embodiment in that the first and second electrodes 1-3 and 2-3 are formed with a similar C-shaped structure, and the guiding element P1 is partially enclosed by the first and second electrodes 1-3 and 2-3. The first slotted portion 1031 of the first electrode 1-3 and the second slotted portion 2031 of the second electrode 2-3 are arranged alternatively with respect to the path g1.

With respect to the first and second electrodes 1-3 and 2-3 corresponding to the first and second positions a1-a1 and b1-b1, respectively, the first and second electrodes 1-3 and 2-3 energize the first fluid w1 therebetween to form a second fluid w2 having an energy state different from that of the first fluid w1, and the second fluid w2 passes through the third position c1-c1 and outputs from the output end i2 of the hollow portion n1.

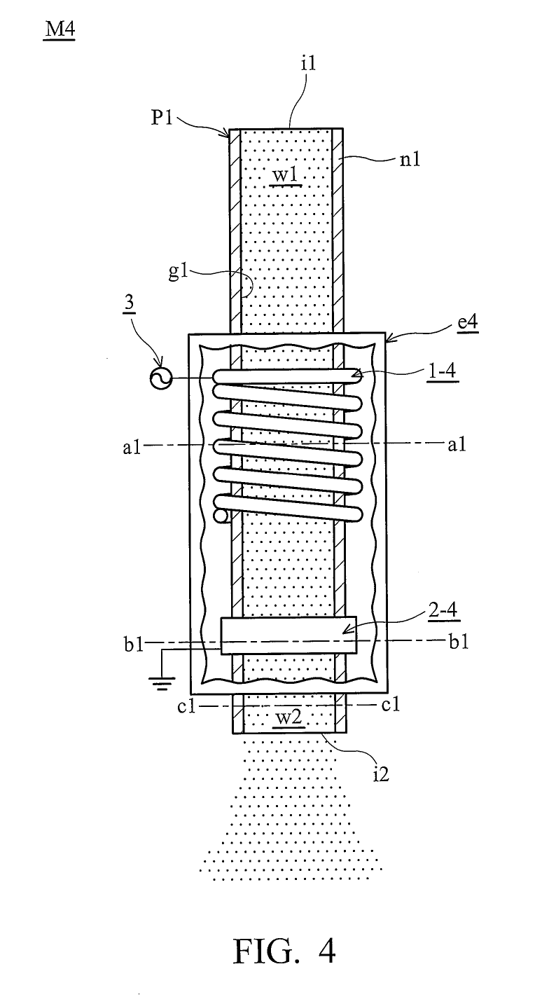

In FIG. 4, a plasma generation device M4 of a forth embodiment of the invention comprises the guiding element P1, the supply device 3, and an electrode element e4 comprising a first electrode 1-4 and a second electrode 2-4. The plasma generation device M4 differs from the plasma generation device M2 of the second embodiment in that the first electrode 1-4 is a coiled structure disposed outside of the guiding element P1.

With respect to the first and second electrodes 1-4 and 2-4 corresponding to the first and second positions a1-a1 and b1-b1, respectively, the first and second electrodes 1-4 and 2-4 energize the first fluid w1 therebetween to form a second fluid w2 having an energy state different from that of the first fluid w1, and the second fluid w2 passes through the third position c1-c1 and outputs from the output end i2 of the hollow portion n1.

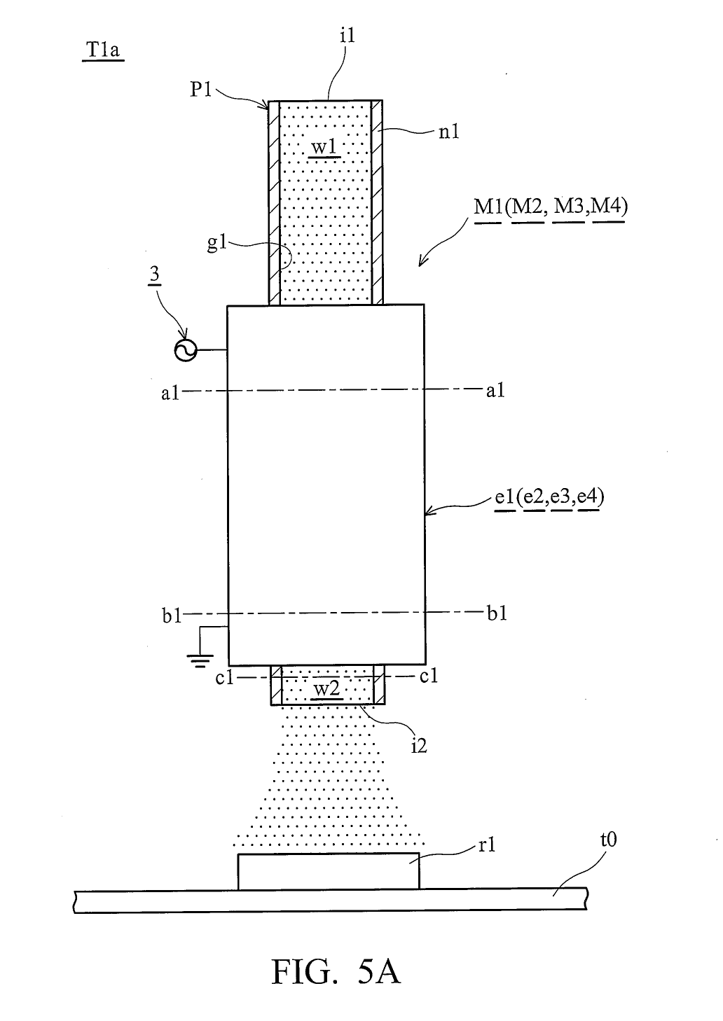

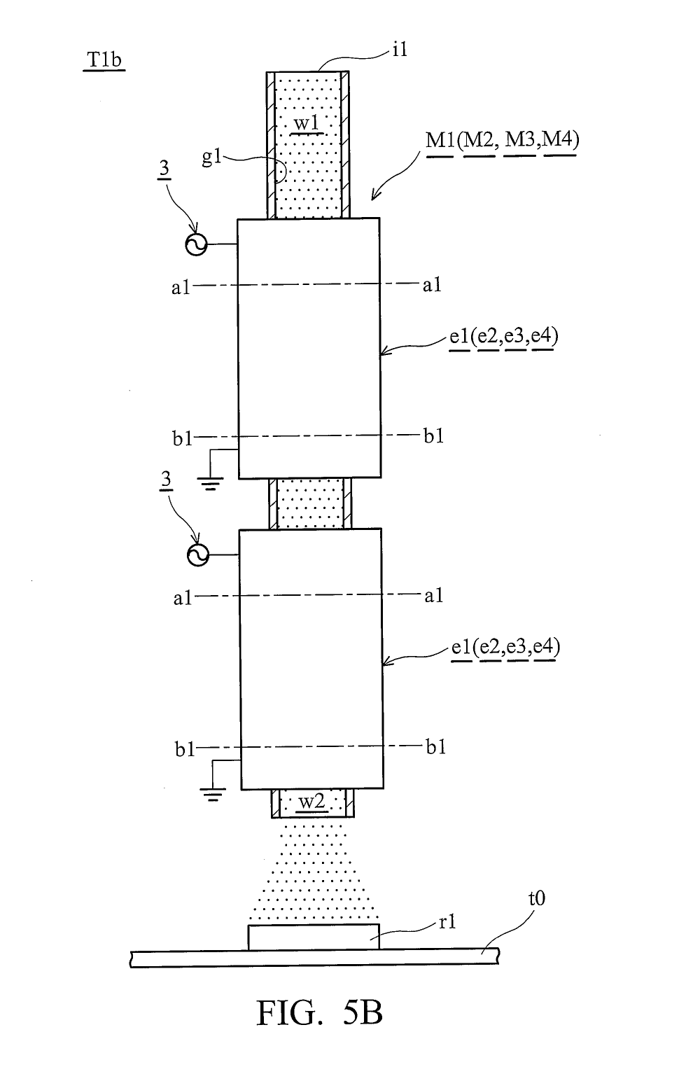

In FIG. 5A, a processing system T1a of a first exemplary application of the invention utilizes a plasma region to process an object r1. The processing system T1a comprises a single plasma generation device M1 and a base t0 supporting the object r1. The following plasma generation device M1 of the exemplary applications can be replaced by the plasma generation device M2, M3 or M4. The second fluid w2, passing through the third position c1-c1 and outputting from the output end i2 of the hollow portion n1, is capable of performing surfacing, activating, cleaning, photoresist ashing or etching process. In this embodiment, the object r1 is a plate or curved member, formed by organic material such as PP, PE, PET, PC, P1, PMMA, PTFE or Nylon, inorganic material such as glass or Si-based material, or metallic material. Due to the uniform energy distribution curve of the second fluid w2 located at the third position c1-c1, the outcome of the described surfacing, activating, cleaning, photoresist ashing or etching process on the plate member r1 is free of defects.

FIG. 5B is a varied example T1b of the processing system T1a of FIG. 5A. The processing system T1b differs from the processing system T1a in that the processing system T1b applies two spaced electrode elements e1 to serially dispose outside of the guiding elements P1. With the two serially spaced electrode elements e1, the effect of the ionizing process of the second fluid w2 is good and the energy density of the second fluid w2 is high.

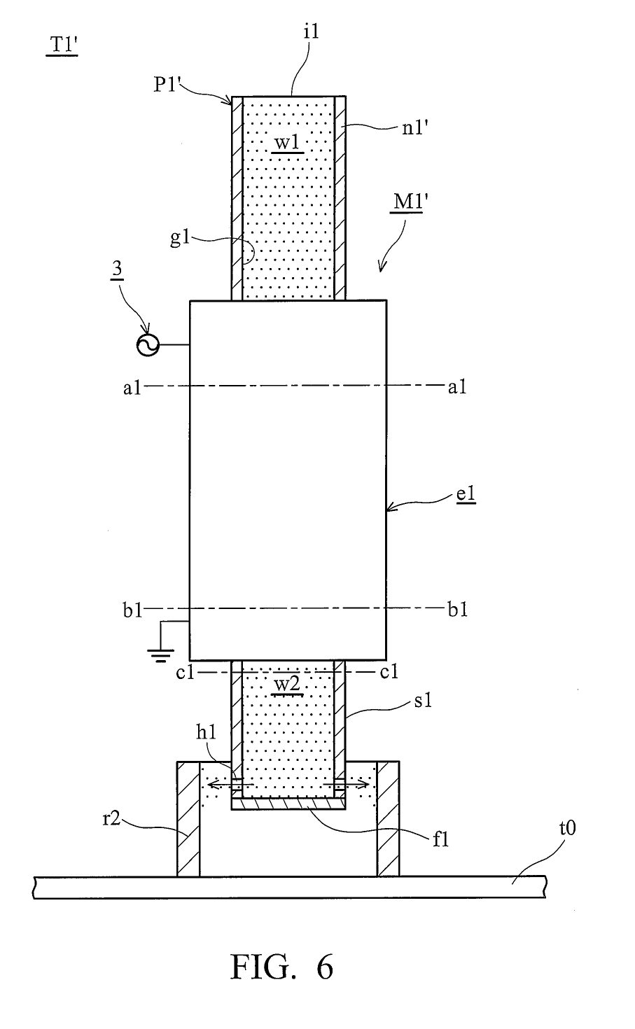

In FIG. 6, a processing system T1′ of a second exemplary application of the invention utilizes a plasma region to process an inner sidewall of an object r2 supported by the base t0. The processing system T1′ differs from the processing system T1a of the first exemplary application in that the hollow portion n1′ of the guiding elements P1′ of the processing system T1′ further provides a sidewall portion s1 and a port structure h1 formed on the sidewall portion s1, and the second fluid w2 passes through the port structure h1 to perform a process, e.g. surfacing, activating, cleaning, photoresist ashing or etching, on the inner sidewall of the object r2. In this embodiment, the object r2 is a pipe-like element formed by organic, inorganic or metallic material.

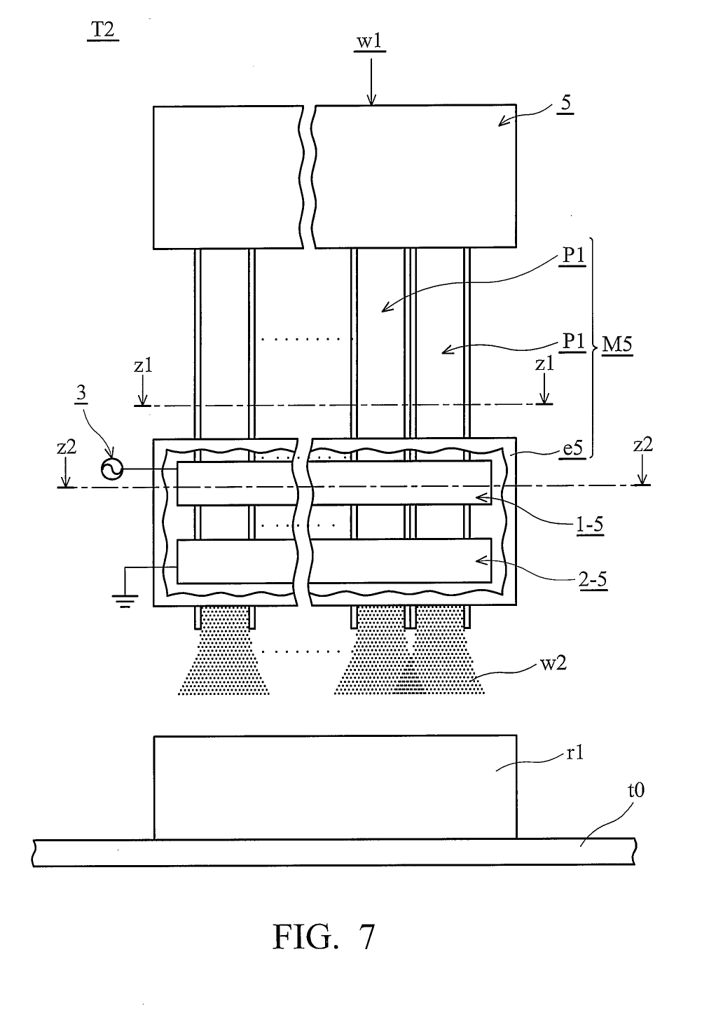

In FIG. 7, a processing system T2 of a third exemplary application of the invention comprises a plasma generation device M5 and a head 5 disposed on the plasma generation device M5. The plasma generation device M5 comprises the guiding elements P1 and an electrode element e5 comprising a first electrode 1-5 and a second electrode 2-5. The head 5 distributes the first fluid w1 to each guiding element P1. The first and second electrodes 1-5 and 2-5 of the electrode element e5 disposed outside of the guiding elements P1 are spaced apart.

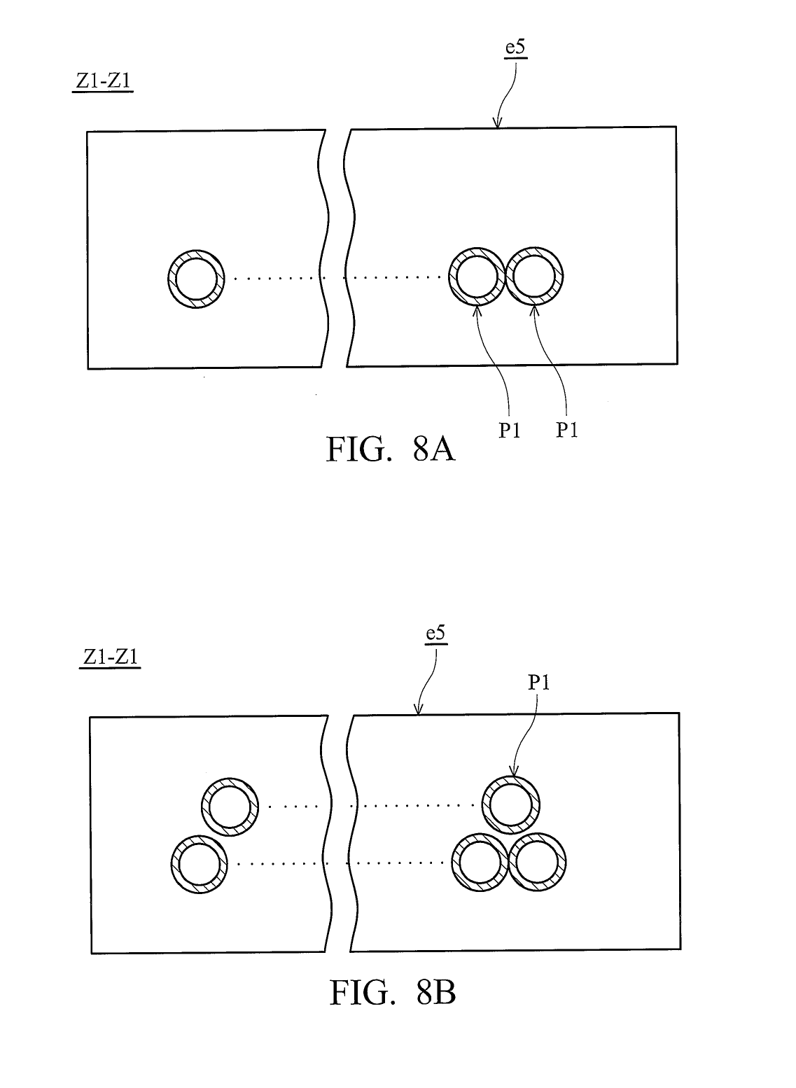

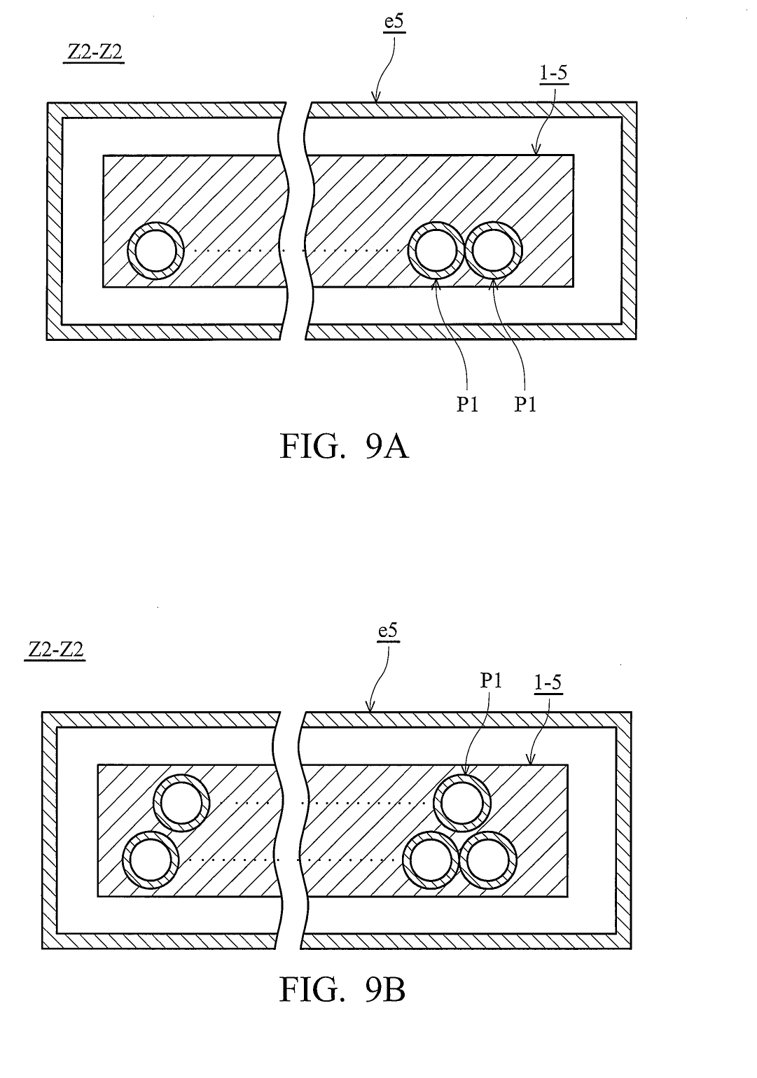

FIG. 8A is a sectional view of the processing system T2 along line Z1-Z1 of FIG. 7. The guiding elements P1 of the processing system T2 are serially arranged. In FIG. 8B, the guiding elements P1 of the processing system T2 of FIG. 8A can be arranged alternatively. In FIG. 9A, a sectional view of the first electrode 1-5 along line Z2-Z2 of FIG. 7, the guiding elements P1 located in the first electrode 1-5 are serially arranged. In FIG. 9B, the guiding elements P1 located in the first electrode 1-5 can be arranged alternatively, thus, the serially and arranged alternatively guiding elements P1 increase the effective area of the plasma region.

Note that the plasma, the first and second electrodes are not contacted to each other, the first and second electrodes have no loss or wear, thus, the equipment cost decreases and the yield can be increased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A plasma generation device for ionizing a first fluid, comprising:
at least one guiding element comprising a path guiding the first fluid to sequentially flow through a first position and a second position; and
at least one electrode element comprising a first electrode corresponding to the first position and a second electrode corresponding to the second position, wherein the first and second electrodes energize the first fluid located between the first and second electrodes to form a second fluid, wherein the energy state of the first fluid is different from that of the second fluid.

2. The plasma generation device as claimed in claim 1, wherein a potential difference exists between the first and second electrodes.

3. The plasma generation device as claimed in claim 1, wherein the guiding element comprises a hollow portion, and the path is located in the hollow portion of the guiding element.

4. The plasma generation device as claimed in claim 1, wherein the first and second electrodes are of the same size.

5. The plasma generation device as claimed in claim 1, wherein the size of the first electrode is greater than that of the second electrode.

6. The plasma generation device as claimed in claim 1, wherein the guiding element is enclosed by the first electrode.

7. The plasma generation device as claimed in claim 1, wherein the guiding element is enclosed by the second electrode.

8. The plasma generation device as claimed in claim 1, wherein the guiding element is partially enclosed by the first electrode.

9. The plasma generation device as claimed in claim 8, wherein the first electrode comprises a similar C-shaped structure.

10. The plasma generation device as claimed in claim 1, wherein the guiding element is partially enclosed by the second electrode.

11. The plasma generation device as claimed in claim 10, wherein the second electrode comprises a similar C-shaped structure.

12. The plasma generation device as claimed in claim 1, wherein the first electrode comprises a first slotted portion and the second electrode comprises a second slotted portion, and the first and second slotted portions are alternatively arranged with respect to the path.

13. The plasma generation device as claimed in claim 1 further comprising a supply device electronically connected to the first electrode.

14. The plasma generation device as claimed in claim 13, wherein the supply device is a radio frequency generator.

15. The plasma generation device as claimed in claim 14, wherein the frequency of the radio frequency generator is equal to 13.56 MHz or a multiple of 13.56 MHz.

16. The plasma generation device as claimed in claim 13, wherein the supply device is a power supply.

17. The plasma generation device as claimed in claim 16, wherein the power supply is an AC generator.

18. The plasma generation device as claimed in claim 17, wherein the frequency of the AC generator ranges from 1 MHz to 100 MHz.

19. The plasma generation device as claimed in claim 1 further comprising a third position through which the second fluid passes and where the energy distribution curve of the second fluid is uniform.

20. The plasma generation device as claimed in claim 1, wherein the guiding element comprises dielectric material.

21. The plasma generation device as claimed in claim 1, wherein the first electrode is a coiled structure.

22. The plasma generation device as claimed in claim 21, wherein the coiled structure is disposed outside the guiding element.

23. The plasma generation device as claimed in claim 1, wherein the guiding element further comprises a sidewall portion and a port structure formed on the sidewall portion, wherein the second fluid passes through the port structure.

24. The plasma generation device as claimed in claim 23, wherein the port structure is a hole.

25. A processing system for processing an object by a first fluid, comprising:
a base supporting the object; and
a plasma generation device ionizing the first fluid, comprising:
at least one guiding element comprising a path guiding the first fluid to sequentially flow through a first position and a second position; and
at least one electrode element comprising a first electrode corresponding to the first position and a second electrode corresponding to the second position, wherein the first and second electrodes energize the first fluid located between the first and second electrodes to form a second fluid, to thereby utilize the second fluid to process the object supported by the base.

26. The processing system as claimed in claim 25, wherein a potential difference exists between the first and second electrodes.

27. The processing system as claimed in claim 25, wherein the guiding element comprises a hollow portion, and the path is located in the hollow portion of the guiding element.

28. The processing system as claimed in claim 25, wherein the first and second electrodes are of the same size.

29. The processing system as claimed in claim 25, wherein the size of the first electrode is greater than that of the second electrode.

30. The processing system as claimed in claim 25, wherein the guiding element is enclosed by the first electrode.

31. The processing system as claimed in claim 25, wherein the guiding element is enclosed by the second electrode.

32. The processing system as claimed in claim 25, wherein the guiding element is partially enclosed by the first electrode.

33. The processing system as claimed in claim 25, wherein the first electrode comprises a similar C-shaped structure.

34. The processing system as claimed in claim 25, wherein the guiding element is partially enclosed by the second electrode.

35. The processing system as claimed in claim 34, wherein the second electrode comprises a similar C-shaped structure.

36. The processing system as claimed in claim 25, wherein the first electrode comprises a first slotted portion and the second electrode comprises a second slotted portion, and the first and second slotted portions are arranged alternatively with respect to the path.

37. The processing system as claimed in claim 25 further comprising a supply device electronically connected to the first electrode.

38. The processing system as claimed in claim 37, wherein the supply device is a radio frequency generator.

39. The processing system as claimed in claim 38, wherein the frequency of the radio frequency generator is equal to 13.56 MHz or a multiple of 13.56 MHz.

40. The processing system as claimed in claim 37, wherein the supply device is a power supply.

41. The processing system as claimed in claim 40, wherein the power supply is an AC generator.

42. The processing system as claimed in claim 41, wherein the frequency of the AC generator ranges from 1 MHz to 100 MHz.

43. The processing system as claimed in claim 25 further comprising a third position through which the second fluid passes and where the energy distribution curve of the second fluid is uniform.

44. The processing system as claimed in claim 25, wherein the guiding element comprises dielectric material.

45. The processing system as claimed in claim 25, wherein the first electrode is a coiled structure.

46. The processing system as claimed in claim 45, wherein the coiled structure is disposed outside the guiding element.

47. The processing system as claimed in claim 25, wherein the guiding element further comprises a sidewall portion and a port structure formed on the sidewall portion, wherein the second fluid passing through the port structure processes the object.

48. The processing system as claimed in claim 47, wherein the port structure is a hole.
